(19) United States
(12) Patent Application Publication
(10) Pub. No.: US 2014/0361788 A1
(43) Pub. Date: Dec. 11, 2014

(54) DETECTION SYSTEM AND METHOD FOR TESTING CONNECTOR

(71) Applicant: HON HAI PRECISION INDUSTRY CO., LTD., New Taipei (TW)

(72) Inventors: CHO-HAO WANG, New Taipei (TW); CHIH-HUANG WU, New Taipei (TW)

(21) Appl. No.: 14/297,871

(22) Filed: Jun. 6, 2014

(30) Foreign Application Priority Data
Jun. 6, 2013 (TW) 102120035

(51) Int. Cl. G01R 31/04

(52) U.S. Cl. CPC G01R 31/04
USPC 324/538

(57) ABSTRACT

A detection system and method are provided. The detection system connects to a connector, and the connector includes a plurality of detection pins. The detection system includes a pin detection circuit and a detection device. The pin detection circuit connects to the plurality of detection pins and obtains output voltages of the detection pins. The pin detection circuit issues a determination voltage signal corresponding to the output voltages of the detection pins. The detection device determines whether the determination voltage signal is a low-level signal and issues a command when the determination voltage signal is a low-level signal.

### CROSS-REFERENCE TO RELATED APPLICATIONS

This application claims priority to Taiwanese Patent Application No. 102120035 filed on Jun. 6, 2013 in the Taiwan Intellectual Property Office, the contents of which are incorporated by reference herein.

### FIELD

The present disclosure relates to detection system and methods and more particularly to a detection system and method for testing a connector.

### BACKGROUND

A connector electrically connects a plurality of electronic components together. Pins of the connector are connected to a circuit board. When one of the pins disconnects from the circuit board, the connector needs to be replaced.

### BRIEF DESCRIPTION OF THE DRAWINGS

The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is an embodiment of a connection diagram of a connector.

FIG. 2 is a block diagram of an embodiment of a detection system of FIG. 1.

FIG. 3 is a circuit diagram of an embodiment of a pin detection circuit of FIG. 2.

FIG. 4 is a flowchart of an embodiment of the detection system of FIG. 2.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “low-level” is defined as close to 0. The term “high-level” is defined as close to a rated voltage, for example 3V, 4.5V and 12V.

The present disclosure is described in relation to a detection system and method. The detection system connects to a connector, and the connector includes a plurality of detection pins. The detection system includes a pin detection circuit and a detection device. The pin detection circuit connects to the plurality of detection pins and obtains output voltages of the detection pins. The pin detection circuit issues determination voltage signals corresponding to the output voltages of the detection pins. The detection device determines whether the determination voltage signal is a low-level signal and issues a command when the determination voltage signal is a low-level signal.

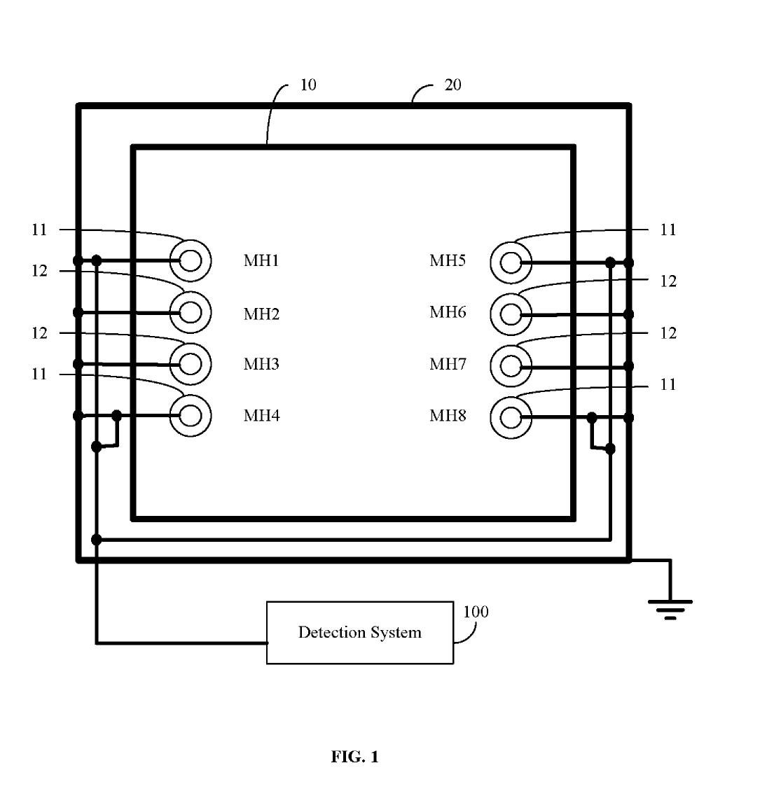

FIG. 1 illustrates an embodiment of a connector 10. The connector 10 includes a plurality of detection pins 11 and a plurality of ground pins 12. The detection pins 11 can include pins MH1, MH4, MH5, and MH8, for example. The ground pins 12 can include pins MH2, MH3, MH6, and MH7, for example. The ground pins 12 electrically couple to a metal housing 20, and the metal housing 20 electrically couples to ground. The detection pins 11 electrically couple to the metal housing 20 and are connected to ground. The detection pins 11 further electrically couple to a detection system 100.

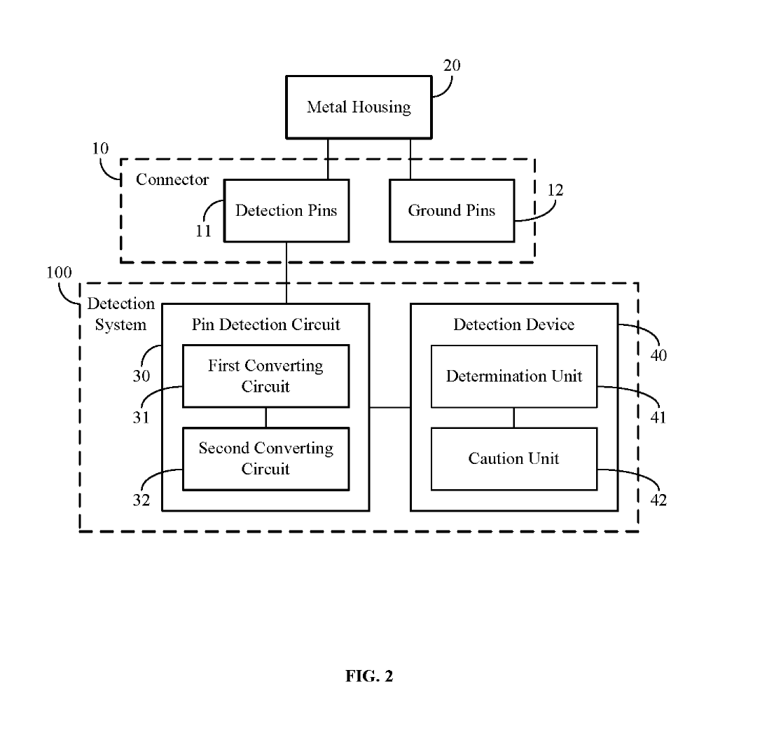

Referring to FIG. 2, the detection system 100 includes a pin detection circuit 30, which is electrically coupled to the detection pins 11 of the connector 10, and a detection device 40, which is electrically coupled to the pin detection circuit 30. The pin detection circuit 30 includes a first converting circuit 31 and a second converting circuit 32. The second converting circuit 32 is electrically coupled to the first converting circuit 31. The detection device 40 includes a determination unit 41 and a caution unit 42. The caution unit 42 is electrically coupled to the determination unit 41.

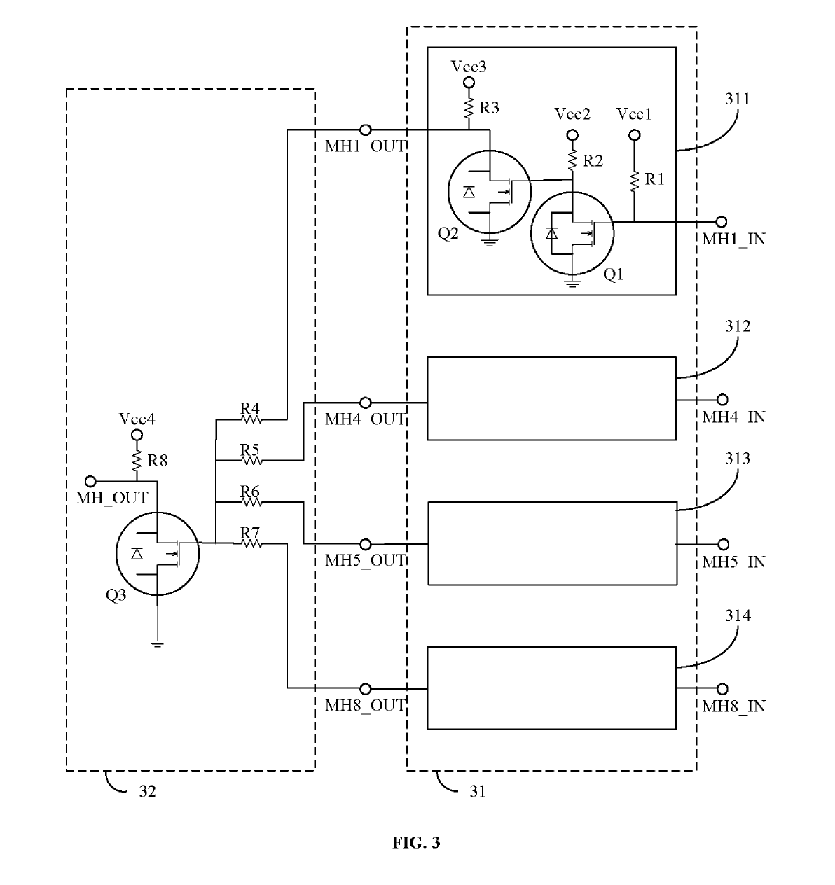

FIG. 3 illustrates an embodiment of the converting circuit 31 and the second converting circuit 32. The first converting circuit 31 converts output voltages of the detection pins 11 from analog form to digital form. The first converting circuit 31 includes a number of first branch converting circuits. Each first branch converting circuit is coupled to one of the corresponding detection pins 11. For example, an MH1 branch converting circuit 311 is electrically coupled to the pin MH1, an MH4 branch converting circuit 312 is electrically coupled to the pin MH4, an MH5 branch converting circuit 313 is electrically coupled to the pin MH5, and an MH8 branch converting circuit 314 is electrically coupled to the pin MH8. The MH1 branch converting circuit 311 includes an input end MH1_IN and an output end MH1_OUT. The MH4 branch converting circuit 312 includes an input end MH4_IN and an output end MH4_OUT. The MH5 branch converting circuit 313 includes an input end MH5_IN and an output end MH5_OUT. The MH8 branch converting circuit 314 includes an input end MH8_IN and an output end MH8_OUT. The input end MH1_IN is coupled to the pin MH1, the input end MH4 in is coupled to the pin MH4, the input end MH5_IN is coupled to the pin MH5, and the input end MH8_IN is coupled to the pin MH8. The output ends MH1_OUT, MH4_OUT, MH5_OUT, and MH8_OUT are all coupled to the second converting circuit 32.

The MH1 branch converting circuit 311 includes resistive components R1, R2, and R3, and further includes transistors Q1 and Q2. A gate terminal of the transistor Q1 couples to a voltage source Vcc1 through the resistive component R1, a drain terminal of the transistor Q1 couples to ground, and a source terminal of the transistor Q1 couples to a voltage source Vcc2 through the resistive component R2. A gate terminal of the transistor Q2 couples to the source terminal of the transistor Q1, a drain terminal of the transistor Q2 couples to ground, and a source terminal of the transistor Q2 couples to a voltage source Vcc3 through the resistive component R3. The MH4 branch converting circuit 312, the MH5 branch converting circuit 313, and the MH8 branch converting circuit 314 each has a substantially similar structure as the MH1 branch converting circuit 311.

The second converting circuit 32 includes resistive components R4, R5, R6, R7, and R8, and further includes a transistor Q3. A gate terminal of the transistor Q3 couples to the output end MH1_OUT of the MH1 branch converting circuit 311 through the resistive component R4, couples to the output end MH4_OUT of the MH4 branch converting circuit 312 through the resistive component R5, couples to the output end MH5_OUT of the MH5 branch converting circuit 313 through the resistive component R6, and couples to the output end MH8_OUT of the MH1 branch converting circuit 314 through the resistive component R7. A drain terminal of the transistor Q3 couples to ground, and a source terminal of the transistor Q3 couples to a voltage source Vcc4 through the resistive component R8.

When the pin MH1 is coupled to ground, the input end MH1_IN obtains a low-level output voltage. When the input end MH1_IN obtains the low-level output voltage, the transistor Q1 is turned off, and the transistor Q2 is turned on. When the transistor Q2 is turned on, the output end MH1_OUT obtains a low-level voltage signal. When all of the pins MH1, MH4, MH5, and MH8 are coupled to ground, the output ends MH1_OUT, MH4_OUT, MH5_OUT, and MH8_OUT all obtain the low-level voltage signal, so the gate terminal of the transistor Q3 obtains a low-level voltage signal, and the transistor Q3 is turned off. Then, the transistor Q3 outputs a high-level determination voltage signal through an output end MH_OUT. If one of the pins MH1, MH4, MH5, and MH8 disconnects from ground, the transistor Q3 outputs a low-level determination voltage signal through the output end MH_OUT.

The determination unit 41 determines whether all of the detection pins 11 are connected to ground according to the output of the second converting circuit 32. If the second converting circuit 32 outputs the high-level determination voltage signal, the determination unit 41 determines that all of the detection pins 11 are connected to ground. If the second converting circuit 32 outputs the low-level determination voltage signal, the determination unit 41 determines that at least one of the detection pins 11 is disconnected from ground and sends a command to the caution unit 42.

In at least one embodiment, the caution unit 42 is a display panel, and the display panel displays a message according to the command received from the determination unit 41. In an alternative embodiment, the caution unit 42 can be an LED light or a loudspeaker. The LED light blinks upon receiving the command, and the speaker broadcasts an audio upon receiving the command.

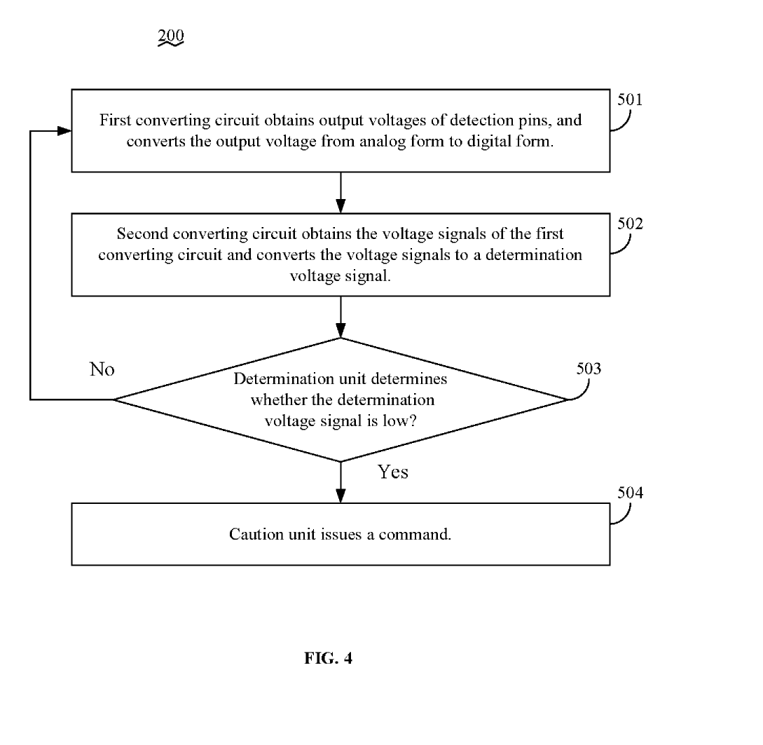

Referring to FIG. 4, a flowchart of an embodiment of an example method 200 is presented. The example method 200 is provided by way of example, as there are a variety of ways to carry out the embodiment. The example method 200 described below can be carried out using the configurations illustrated in FIG. 2, and various elements of these figures are referenced in explaining the example method 200. Each block shown in FIG. 4 represents one or more processes, methods, or subroutines, carried out in the exemplary method 200. Additionally, the illustrated order of blocks is by example only and the order of the blocks can change. The example method 200 can begin at block 501.

At block 501, a first converting circuit obtains output voltages of detection pins, and converts the output voltage from analog form to digital form. When the detection pins connect to ground, the first converting circuit obtains a low-level output voltage from each detection pin, and outputs a low-level voltage signal corresponding to the low-level output voltages. If one of the detection pins disconnects from ground, the first converting circuit obtains a high-level output voltage from the disconnected detection pin, and outputs a high-level voltage signal corresponding to the high-level output voltage.

At block 502, a second converting circuit obtains the voltage signals of the first converting circuit and converts the voltage signals into a determination voltage signal. Specifically, if all of the voltage signals sent from the first converting circuit are low-level, the second converting circuit converts the voltage signals into a high-level determination voltage signal. If at least one of the voltage signals sent from the first converting circuit is high-level, the second converting circuit converts the voltage signals into a low-level determination voltage signal.

At block 503, a determination unit determines whether the determination voltage signal of the second converting circuit is low-level, if the determination voltage signal of the second converting circuit is low-level, block 504 is implemented. Otherwise, if the determination voltage signal is high-level, block 501 is implemented.

At block 504, a caution unit issues a command. In at least one embodiment, the caution unit is a display panel, and the display panel displays a text message according to the command. In an alternative embodiment, the caution unit can be an LED light or a loudspeaker. The LED light can blink according to the command, and the speaker can broadcast an audio according to the command.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in particular matters of shape, size and arrangement of the parts within the principles of the present disclosure, up to and including the full extent established by the broad general meaning of the terms used in the claims.

What is claimed is:

1. A detection system for testing a connector, the connector comprises a plurality of detection pins, the detection system comprising:
a pin detection circuit configured to detect output voltages of the plurality of detection pins and issues a determination voltage signal according to the output voltages of the detection pins, and
a detection device configured to determine whether the determination voltage signal is a low-level signal and issue a command when the determination voltage signal is a low-level signal.

2. The detection system of claim 1, wherein the pin detection circuit comprises:
a first converting circuit configured to convert the output voltages of the detection pins to voltage signals, and
a second converting circuit configured to convert the voltage signals of the first converting circuit to the determination voltage signal.

3. The detection system of claim 2, wherein the first converting circuit comprises a plurality of branch converting circuits, each of the plurality of branch converting circuits connects to one of the detection pins, the first converting circuit connected to the detection pin obtains a low-level output voltage when the detection pin is coupled to ground, and the converting circuit further convert the low-level output voltage to a low-level voltage signal, the converting circuit obtains a high-level output voltage when the detection pin is not coupled to ground, and the converting circuit further convert the high-level output voltage to a high-level voltage signal.

4. The detection system of claim 3, wherein the second converting circuit connects to the plurality of branch converting circuits, when all the voltage signals of the first converting circuit are low-level signals, the second converting circuit converts the voltage signals to a high-level determination voltage signal; when one of the voltage signals of the first converting circuit is a high-level signal, the second converting circuit converts the voltage signals to a low-level determination voltage signal.

5. The detection system of claim 1, wherein the detection device comprising:
a determination unit configured to determine whether the determination voltage signal is a low-level signal; and
a caution unit configured to issue the command when the determination voltage signal is a low-level signal.

6. The detection system of claim 5, wherein the caution unit is a display panel configured to output the command in a text message format.

7. The detection system of claim 5, wherein the caution unit is a LED light configured to output the command in a light shining format.

8. The detection system of claim 5, wherein the caution unit is a loudspeaker configured to output the command in an audio format.

9. A detection method for testing a connector, the connector comprises a plurality of detection pins, the detection method comprising:
detecting output voltages of the plurality of the detection pins and issuing a determination voltage signal according to the output voltages of the detection pins, and
determining whether the determination voltage signal is a low-level signal and issuing a command when the determination voltage signal is a low-level signal.

10. The detection method of claim 9, wherein detecting output voltages of the plurality of the detection pins and issuing a determination voltage signal according to the output voltages of the detection pins comprises:
converting the output voltages of the detection pins to voltage signals, and
converting the voltage signals to the determination voltage signal.

11. The detection method of claim 10, wherein converting the output voltages of the detection pins to voltage signals comprises:
obtaining a low-level output voltage when one of the detection pins is coupled to ground normally and converting the low-level output voltage to a low-level voltage signal, and obtaining a high-level output voltage when one of the detection pins is not coupled to ground and converting the high-level output voltage to a high-level voltage signal.

12. The detection method of claim 11, wherein converting the voltage signals to the determination voltage signal comprises:
converting the voltage signals to a high-level determination voltage signal when all the voltage signals are low-level signals, and converting the voltage signals to a low-level determination voltage signal when one of the voltage signals is a high-level signal.

13. The detection method of claim 9, wherein determining whether the determination voltage signal is a low-level signal and issuing a command when the determination voltage signal is a low-level signal comprises:
determining whether the determination voltage signal is a low-level signal, and
issuing the command when the determination voltage signal is a low-level signal.
